(19) United States
(12) Patent Application Publication
(10) Pub. No.: US 2024/0204482 A1
(43) Pub. Date: Jun. 20, 2024

(54) LASER RADAR DEVICE FOR IMPROVING ACCURACY OF CALCULATION

(71) Applicant: HON HAI PRECISION INDUSTRY CO., LTD., New Taipei (TW)

(72) Inventors: KUO-FONG TSENG, New Taipei (TW); YU-TING LIAO, New Taipei (TW)

(21) Appl. No.: 18/538,197

(22) Filed: Dec. 13, 2023

(30) Foreign Application Priority Data
Dec. 15, 2022 (CN) 202211613001.4

(51) Int. Cl. H01S 5/062; G01S 7/481; G01S 7/4915; G01S 17/32; H01S 5/042; G01S 7/499

(52) U.S. Cl. CPC H01S 5/06243; G01S 7/4814; G01S 7/4915; G01S 17/32; H01S 5/04256; H01S 5/06246; G01S 7/499

(57) ABSTRACT

A laser radar device includes a light source module, a collimating module, an optical phase-controlled array, a processing module, and a receiving module. The collimating module collimates the laser beam emitted by the light source module. The optical phase-controlled array deflects the collimated laser beam and reflects the deflected laser beam for making the reflected laser beam to illuminate at a target object. The receiving module receives the laser beam reflected by the target object and converts the received laser beam into electric signals. The processing module calculate a distance between the laser radar device and the target object based on the received electric signals. An accuracy of calculating the distance between the laser radar device and the target object is improved.

### FIELD

The subject matter herein generally relates to laser radar.

### BACKGROUND

A laser radar system emits laser beam for detecting features related to a target object, such as a position of the target object and the speed of the target object. The laser beam reflected by the target object is received and compared with the emitted laser beam. By further processing, the features related to the target object are obtained, such as a distance, a position, a height, a speed, a posture, and a shape, and the like. Thus, the target object, such as a plane or a guided missile, can be detected, tracked, and identified. For measuring a distance, a scanning angle formed by turning the laser beam is limited, and a deflection efficiency of the laser beam is low, which cause a measure result to be poor.

There is room for improvement in the art.

### BRIEF DESCRIPTION OF THE DRAWINGS

Implementations of the present disclosure will now be described, by way of example only, with reference to the attached figures.

FIG. 1 is diagram illustrating an embodiment of a laser radar device according to the present disclosure, the laser radar device comprises an optical phase-controlled array.

FIG. 2 is a diagram illustrating an embodiment of optical phase-controlled array of FIG. 2 according to the present disclosure.

FIG. 3 is an exploded diagram illustrating an embodiment of optical phase-controlled array of FIG. 2 according to the present disclosure, the optical phase-controlled array includes an electrode layer.

FIG. 4 is a diagram illustrating a first embodiment of the electrode layer of FIG. 3 according to the present disclosure.

FIG. 5 is a diagram illustrating a second embodiment of the electrode layer of FIG. 3 according to the present disclosure.

FIG. 6 is a diagram illustrating an embodiment of a relationship between sizes of the electrode in FIG. 4 and deflection efficiencies according to the present disclosure.

FIG. 7 is a diagram illustrating an embodiment of the laser beam entered into the optical phase-controlled array of FIG. 2 and the laser beam being outputted from the optical phase-controlled array of FIG. 2 according to the present disclosure.

### DETAILED DESCRIPTION

The present disclosure is described with reference to accompanying drawings and the embodiments. It will be understood that the specific embodiments described herein are merely part of all embodiments, not all the embodiments. Based on the embodiments of the present disclosure, it is understandable to a person skilled in the art, any other embodiments obtained by persons skilled in the art without creative effort shall all fall into the scope of the present disclosure. It will be understood that the specific embodiments described herein are merely some embodiments and not all.

It will be understood that, even though the flowchart shows a specific order, an order different from the specific order shown in the flowchart can be implemented. The method of the present disclosure can include one or more steps or actions for achieving the method. The steps or the actions in the method can be interchanged with one another without departing from the scope of the claims herein.

In general, the word “module,” as used herein, refers to logic embodied in hardware or firmware, or to a collection of software instructions, written in a programming language, for example, Java, C, or assembly. One or more software instructions in the modules may be embedded in firmware, such as an EPROM, magnetic, or optical drives. It will be appreciated that modules may comprise connected logic units, such as gates and flip-flops, and may comprise programmable units, such as programmable gate arrays or processors, such as a CPU. The modules described herein may be implemented as either software and/or hardware modules and may be stored in any type of computer-readable medium or other computer storage systems. The term “comprising” means “including, but not necessarily limited to”; it specifically indicates open-ended inclusion or membership in a so-described combination, group, series, and the like. The disclosure is illustrated by way of example and not by way of limitation in the figures of the accompanying drawings in which like references indicate similar elements. It should be noted that references to “an” or “one” embodiment in this disclosure are not necessarily to the same embodiment, and such references can mean “at least one.”

Terms “first”, “second”, and the like used in the specification, the claims, and the accompanying drawings of the present disclosure are used to distinguish different objects rather than describe a particular order. A term “comprise” and its variations are intended to cover a non-exclusive inclusion. For example, a process, method, system, product, or apparatus including a series of steps or units is not limited to the listed steps or units, and may optionally include other steps or units that are not listed, or other steps or units inherent to the process, method, product, or device.

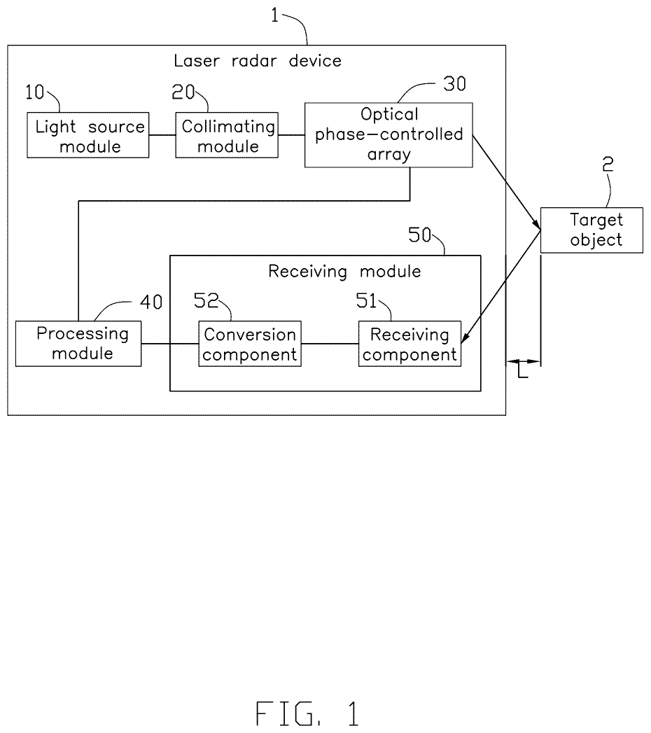

FIG. 1 shows a laser radar device 1 of the present disclosure. The laser radar device 1 may accurately measure a distance between the laser device 1 and a target object 2. The laser radar device 1 includes a light source module 10, a collimating module 20, an optical phase-controlled array 30, a processing module 40, and a receiving module 50.

The light source 10 emits laser beam. In some embodiments, the light source module may include multiple light sources for emitting different laser beams.

The collimating module 20 is located on a propagation direction of the laser beam emitted by the light source module 10. The collimating module 20 may collimate the laser beam for integrating the laser beams into a collimated laser beam and emits the collimated laser beam. In some embodiment, the collimating module 10 may be collimating lens.

The optical phase-controlled array 30 is located on the propagation direction of the laser beam after the collimating module 20. The optical phase-controlled array 30 may deflect the collimated laser beam when being powered, and reflect the deflected laser beam for illuminating the reflected laser beam at a scanning angle. In detail, in some embodiments, the optical phase-controlled array 30 processes the received laser beam emitted by the collimating module 20 for turning the deflected laser beam to the target object 2. In some embodiments, the optical phase-controlled array 30 may be an optical parameter amplification (OPA) chip.

The processing module 40 is electrically connected with the optical phase-controlled array 30. The processing module 40 controls a value of a voltage provided to the optical phase-controlled array 30 for controlling a deflection angle of the laser beam.

The receiving module 50 is electrically connected with the processing module 40. The receiving module 50 receives the laser beam reflected by the target object 2, and converts the reflected laser beam into electronic signals to transmit to the processing module 40. The processing module 40 receives the transmitted electronic signals and calculates a distance between the laser radar device 1 and the target object 2.

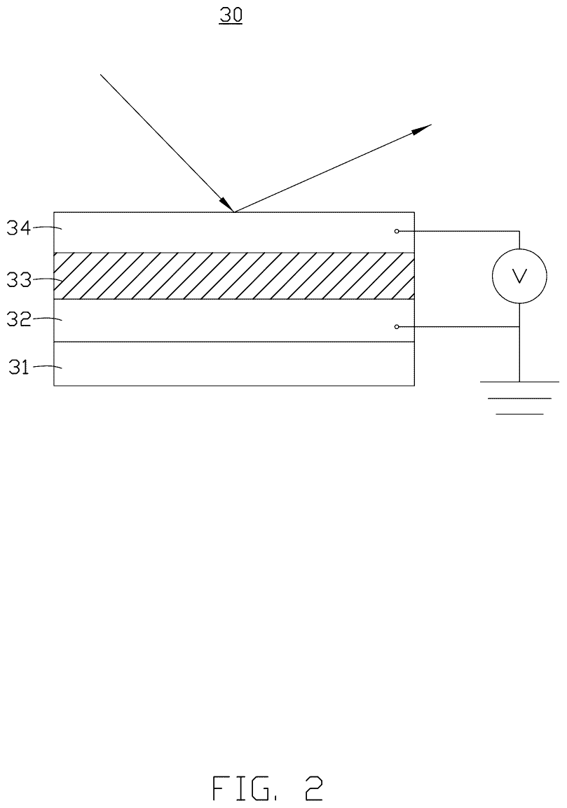

FIG. 2 shows the optical phase-controlled array 30. In detail, the optical phase-controlled array 30 may include a conducting layer 34, a dielectric layer 33, an electrode layer 32, and a base 31, which are arranged in that order.

The conducting layer 34 may be a transparent layer. The conducting layer 34 receives the collimated laser beam and reflects the received laser beam. In some embodiments, the conducting layer 34 may be a transparent layer with Indium Tin Oxide (ITO), Indium Zinc Oxide (IZO), Aluminum-dopped Zinc Oxide (AZO), Gallium Zinc Oxide (GZO), Aluminum Gallium Zinc Oxide (AGZO), or Gallium Indium Zinc Oxide (GIZO).

A power supply V is electrically connected between the conducting layer 34 and the electrode layer 32. The power supply V provides voltages to the conducting layer 34 and the electrode layer 32. When the conducting layer 34 and the electrode layer 32 being powered, an electric field is formed between the conducting layer 34 and the electrode layer 32. In some embodiments, the electrode layer 32 may be made of metal material. The electrode layer 32 may be formed by a combination of Au with any one metal from the group consisting of Cu, AL, Ni, Fe, Co, Zn, Ti, Ru, Rh, Pd, Pt, Ag, Os, Ir.

The dielectric layer 33 is polarized by the electric field formed by the conducting layer 34 and the electrode layer 32 to generate carriers. A carrier concentration may be adjusted based on the value of the voltage of the electric field. When the carrier concentration changes, a reflective index of the dielectric layer 33 is changed, and a phase delay is generated while the laser beam enters the conducting layer 34 for changing a phase of the laser beam. Thus, an illuminating direction is deflected. In some embodiments, the dielectric layer 33 may be made of insulating silicon compound or an insulating metal compound. The insulating silicon compound may include, for example, silicon oxide (SiOx), silicon nitride (SixNy), or silicon oxynitride (SiON). The insulating metal compound may include, for example, aluminum oxide (Al2O3), hafnium oxide (HfO), zirconium oxide (ZrO), or hafnium silicon oxide (HfSiO).

The base 31 may be serve as an insulating layer for insulating the electrode layer 32. In some embodiments, the base 31 may be an insulating layer made of silicon dioxide.

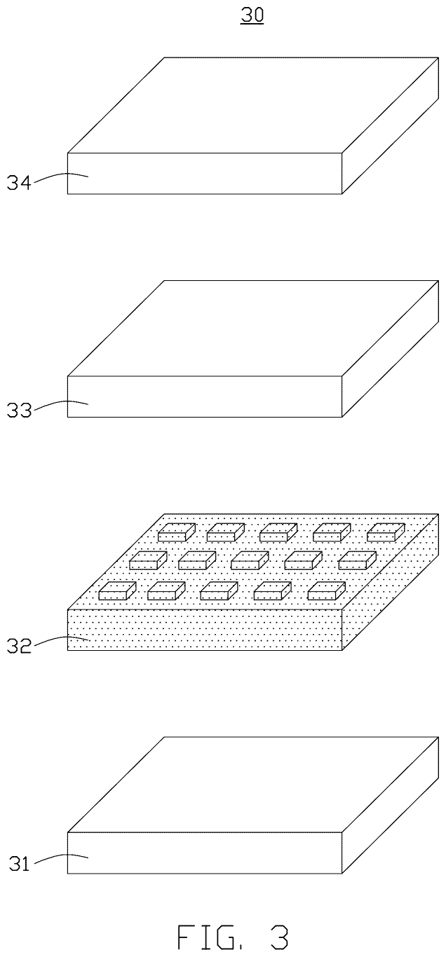

FIG. 3 shows the electrode layer 32. The electrode layer 32 may include a plurality of electrodes 321 located on a surface of the electrode layer 32 facing to the dielectric layer 33, which are arranged in a regular array. A surface of the dielectric layer 33 facing to the electrode layer 32 defines receiving slots corresponding to the electrodes 321, thus the dielectric layer 33 is fitted with the electrode layer 32. The electrodes 321 of the electrode layer 32 are used for changing a distribution of the electric field. Therefore, the carrier concentration generated by the dielectric layer 33 is changed, and the reflective index of the conducting layer 34 is also changed for adjusting the deflection angle of the laser beam. In some embodiments, the electrodes 321 of the electrode layer 32 may be a projection with a common size.

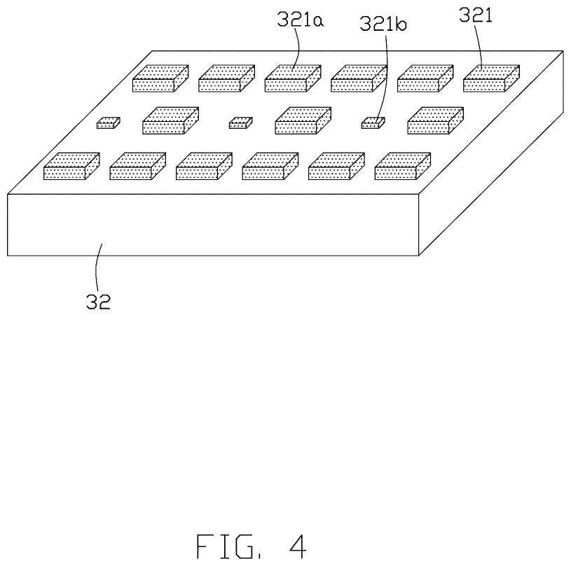

FIG. 4 shows a first embodiment of the electrode layer 32. In some embodiments, the electrode layer 32 may include a plurality of electrodes 321 in different sizes. For example, the size of the electrode 321a is different from the size of the electrode 321b.

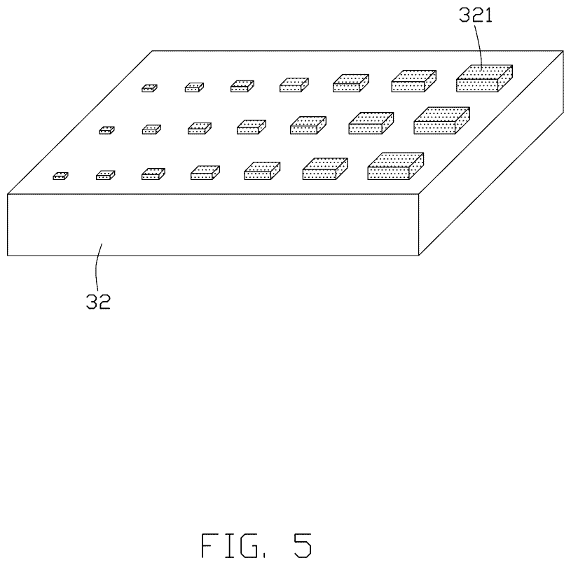

FIG. 5 shows a second embodiment of the electrode layer 32. The sizes of the electrodes 321 are increased by an equal difference according to the arrangement of the electrodes 321.

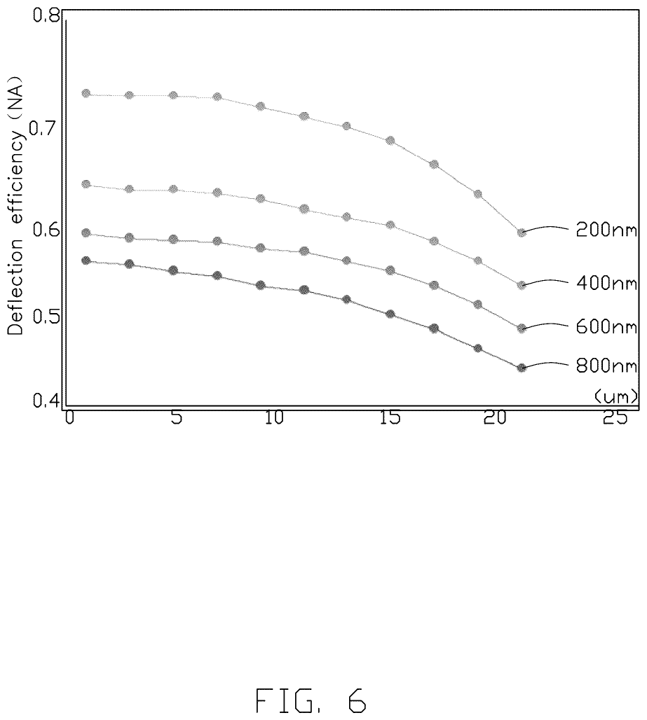

FIG. 6 shows a relationship between the deflection efficiency and the size of the electrode 321. As shown in FIG. 6, when the size of the electrode 321 becomes smaller, the deflection efficiency of the laser beam is improved in different wavelengths. Sizes of a part of the electrode 321 on the electrode layer 32 may be smaller for increasing the deflection efficiency of the laser beam.

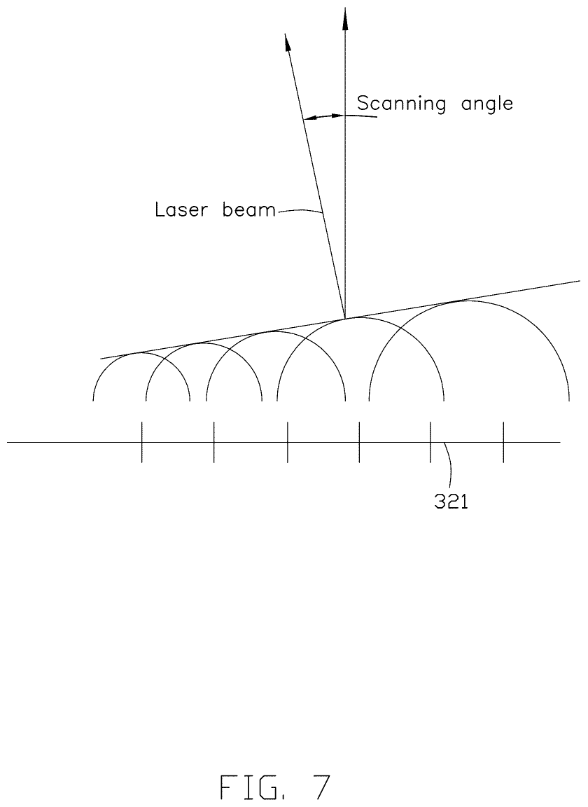

Referring to FIGS. 1 and 7, when the illuminating direction of the laser beam is adjusted to face a to-be-scanned position under the scanning angle, the processing module 40 adjusts the voltage provided to the optical phase-controlled array 30, and the distribution of the electric field is changed by the electrodes 321 of the electrode layer 32 for adjusting the carrier concentration of the dielectric layer 33. Thus, the phase delay of the laser beam entered into the conducting layer 34 is generated, which cause the phase of the laser beam to be changed. The illuminating direction of the laser beam is deflected to the corresponding scanning angle, and the laser beam is reflected to the target object by the optical phase-controlled array 30. The laser beam is further reflected by the target object 2.

The receiving module 50 may include a receiving component 51 and a conversion component 52. The receiving component 51 receives the laser beam reflected by the target object 2, and transmits the laser beam to the conversion component 52. The conversion component 52 is electrically connected with the processing module 40. The conversion component 52 coverts the received laser beam from the receiving component 51 into electrical signals, and transmits the electrical signals to the processing module 40.

The processing module 40 further receives the electrical signals from the conversion component 52, and calculates a distance between the laser radar device 1 and the target object 2. The processing module 40 calculates the distance L between the laser radar device 1 and the target object 2 according to the following formular.

$$L = T / 2 \times S$$

L represents the distance between the laser radar device 1 and the target object 2. T represents a photon flight time. S represents a speed of light. The photon flight time may be a time duration taken by the laser beam emitted from the optical phase-controlled array 30 to reach the target object 2 and being received by the receiving component 51.

In some embodiments, by adjusting the arrangement of the electrodes 132 and the value of the voltage provided to the optical phase-controlled array 30, the carrier concentration of the dielectric layer 33, the reflective index of the conducting layer 34, the phase of the laser beam may be adjusted. The illuminating direction of the laser beam is deflected to be faced to the target object 2 accurately. Therefore, the distance between the laser radar device 1 and the target object 2 is accurately calculate according to the photon flight time of the laser beam.

Based on the structure of the laser radar device 1, the laser beam is deflected by the optical phase-controlled array 30 to be illuminated on the target object 2. The electrodes 321 on the electrode layer 32 controls the distribution of the electric field when the optical phase-controlled array 30 being powered, which cause the carrier concentration generated by the dielectric layer 33 and the reflective index of the conducting layer 34 to be changed. The phase of the laser beam entered into the conducting layer 34 is changed, and the illuminating direction of the laser beam is deflected. Due to a smaller size of the electrodes 132, the deflection efficiency of the laser beam is improved, an accuracy of the laser beam being illuminated at the target object 2 is improved, and an accuracy of calculating the distance between the laser radar device 1 and the target object 2 is also improved.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A laser radar device comprising:
a light source module, configured to emit laser beam;
a collimating module, configured to collimate the laser beam;
an optical phase-controlled array, configured to deflect the collimated laser beam and reflect the deflected laser beam for making the reflected laser beam to illuminate at a target object;
a receiving module, configured to receive the laser beam reflected by the target object and convert the received laser beam into electric signals; and
a processing module, configured to receive the electric signals and calculate a distance between the laser radar device and the target object based on the electrical signals.

2. The laser radar device of claim 1, wherein the optical phase-controlled array comprises a conducting layer and an electrode layer; the conducting layer receives the collimated laser beam and reflects the laser beam; when the conducting layer and the electrode layer being powered, an electric field is formed between the conducting layer and the electrode layer.

3. The laser radar device of claim 2, wherein the optical phase-controlled array further comprises a dielectric layer; the dielectric layer is located between the conducting layer and the electrode layer; the dielectric layer generates carrier based on the electric field formed between the conducting layer and the electrode layer and adjusts a carrier concentration according to a voltage of the electrical field.

4. The laser radar device of claim 3, wherein the electrode layer comprises a plurality of electrodes located on a surface of the electrode layer facing to the dielectric layer; a surface of the dielectric layer facing to the electrode layer defines receiving slots corresponding to the electrodes.

5. The laser radar device of claim 3, wherein when the carrier concentration changes, a reflective index of the conducting layer is changed.

6. The laser radar device of claim 1, wherein the receiving module comprises a receiving component and a conversion component; the receiving component receives the laser beam reflected by the target object and transmits the laser beam to the conversion component; the conversion component coverts the received laser beam from the receiving component into electrical signals and transmits the electrical signals to the processing module.

7. The laser radar device of claim 4, wherein the optical phase-controlled array further comprises a base; the conducting layer, the dielectric layer, the electrode layer, and the base are arranged in that order.

8. The laser radar device of claim 4, wherein a size of at least one of the electrodes is different from the size of the other electrodes.

9. The laser radar device of claim 4, wherein the sizes of the electrodes are different from each other and the electrodes are arranged according to the sizes of the electrodes.

10. The laser radar device of claim 9, wherein the sizes of the electrodes are increased by an equal difference according to the arrangement of the electrodes.
